(19) United States
(12) Patent Application Publication
(10) Pub. No.: US 2022/0393121 A1
(43) Pub. Date: Dec. 8, 2022

(54) SUPPORTING MEMBER OF FLEXIBLE DISPLAY MODULE AND PREPARATION METHOD THEREFOR, FLEXIBLE DISPLAY MODULE, AND DISPLAY DEVICE

(71) Applicant: BOE Technology Group Co., Ltd., Beijing (CN)

(72) Inventors: Penghao GU, Beijing (CN); Yonghong ZHOU, Beijing (CN); Hao GAO, Beijing (CN); Song ZHANG, Beijing (CN)

(21) Appl. No.: 17/773,022

(22) PCT Filed: Jun. 11, 2021
(86) PCT No.: PCT/CN2021/099774

§ 371 Date: Apr. 28, 2022

(30) Foreign Application Priority Data
Jul. 20, 2020 (CN) 202010697555.1

(51) Int. Cl. H01L 51/00; H01L 51/56

(52) U.S. Cl. CPC H01L 51/0097; H01L 51/56; H01L 27/3244

(57) ABSTRACT

A supporting member of flexible display module and a preparation method therefor, the flexible display module, and a display device. The supporting member includes a substrate made of a metal material, a first planarization layer, and a second planarization layer; a plurality of through holes are formed on the substrate; the plurality of through holes run through a first surface and a second surface of the substrate which are opposite to each other; the first planarization layer is provided on the first surface; the second planarization layer is provided on the second surface and is filled into the plurality of through holes. The preparation method for the supporting member includes: forming a first planarization layer on a first surface of a substrate made of a metal material; forming a plurality of through holes on the substrate; and forming a second planarization layer on the second surface of the substrate.

### CROSS-REFERENCE TO RELATED APPLICATIONS

The present application is a U.S. National Phase Entry of International Application PCT/CN2021/099774 having an international filing date of Jun. 11, 2021, which claims priority of Chinese Patent Application No. 202010697555.1 entitled “Supporting member of Flexible Display Module and Preparation Method Therefor, Flexible Display Module, and Display Device” and filed on Jul. 20, 2020, the contents disclosed in the above-mentioned applications are hereby incorporated as a part of this application.

### TECHNICAL FIELD

Embodiments of the present disclosure relate to, but are not limited to, the field of display technologies, and in particular relates to a supporting member of flexible display module and a method for preparing the supporting member of flexible display module, a flexible display module, and a display device.

### BACKGROUND

Organic Light Emitting Display (OLED) has gradually become the first choice for a screen, which has many advantages, such as self-illumination, high luminous efficiency, short response time and high definition and contrast, while ensuring certain flexibility and adaptability of the screen. With the development of flexible display screens, people have higher and higher expectations for foldable and curved display products.

Some flexible display modules include supporting members made of metal materials. In order to meet requirements of bending or rolling of flexible display modules, supporting members are required to have high level of deformation capability.

### SUMMARY

The following is a summary of subject matters described herein in detail. The summary is not intended to limit the scope of protection of claims.

An embodiment of the present disclosure provides a supporting member of a flexible display module. The supporting member includes a substrate of a metal material, a first planarization layer and a second planarization layer, wherein the substrate is provided with multiple through holes, the multiple through holes run through a first surface and a second surface of the substrate which are opposite to each other, the first planarization layer is provided on the first surface, and the second planarization layer is provided on the second surface and filled in the multiple through holes.

An embodiment of the present disclosure further provides a flexible display module, including a supporting structure layer and a display structure layer provided on the supporting structure layer, wherein the supporting structure layer includes the supporting member of the flexible display module, and the first planarization layer is provided towards the display structure layer.

An embodiment of the present disclosure further provides a display device, including the flexible display module.

An embodiment of the present disclosure further provides a method for preparing a supporting member of the flexible display module, including:

forming a first planarization layer on a first surface of a substrate of a metal material;

forming multiple through holes on the substrate, wherein the multiple through holes run through the first surface and a second surface of the substrate which are opposite to each other; and

forming a second planarization layer on the second surface of the substrate, and the second planarization layer is provided on the second surface of the substrate and filled in the multiple through holes.

Other aspects may be understood upon reading and understanding of the accompanying drawings and detailed descriptions.

### BRIEF DESCRIPTION OF DRAWINGS

Accompanying drawings are used to provide an understanding of embodiments of the present disclosure, form a part of the specification, and are used to explain technical solutions of the embodiments of the present disclosure together with the embodiments of the present disclosure, but are not intended to form limitations on the technical solutions of the embodiments of the present disclosure.

FIG. 1 is a schematic diagram of a structure of some flexible display modules.

FIG. 2 is a schematic diagram of a structure of some other flexible display modules.

FIG. 3 is a schematic diagram of a structure of pits in a planarization layer of the supporting member in FIG. 2 forming stamps in a flexible display module.

FIG. 4 is a schematic diagram of a structure of some other flexible display modules.

FIG. 5 is a schematic diagram of a structure of the flexible display module of FIG. 4 fixed to an overall unit frame of the display device.

FIG. 6 is a schematic top view of a structure of a supporting member of a flexible display module according to some exemplary embodiments.

FIG. 7 is another schematic top view of a structure of a supporting member of a flexible display module according to some exemplary embodiments.

FIG. 8 is a schematic diagram of a structure of a supporting member of a flexible display module according to some exemplary embodiments.

FIG. 9 is a schematic diagram of a structure after a first planarization layer is formed on a first surface of a substrate of a metal material according to some exemplary embodiments.

FIG. 10 is a schematic diagram of a structure after photoresist is coated on a second surface of the substrate of the metal material of FIG. 9 according to some exemplary embodiments.

FIG. 11 is a schematic diagram of a structure after exposure of the photoresist of FIG. 10 according to some exemplary embodiments.

FIG. 12 is a schematic diagram of a structure after development of the exposed photoresist of FIG. 11 and etching of the substrate according to some exemplary embodiments.

FIG. 13 is a schematic diagram of a structure after the photoresist in FIG. 12 are removed according to some exemplary embodiments.

FIG. 14 is a schematic diagram of a structure after a second planarization layer is formed on a second surface of the substrate in FIG. 13 according to some exemplary embodiments.

FIG. 15 is a schematic diagram of a structure of a flexible display module fixed to an overall unit frame of a display device according to some exemplary embodiments.

FIG. 16 is a schematic diagram of a structure of a flexible display module fixed to an overall unit frame of a display device according to some other exemplary embodiments.

FIG. 17 is a schematic diagram of a structure of a display structure layer of a flexible display module according to some exemplary embodiments.

### DETAILED DESCRIPTION

Those of ordinary skills in the art should understand that modifications or equivalent replacements may be made to the technical solutions of the disclosure without departing from the spirit and scope of the technical solutions of the disclosure, and should fall within the scope of the claims of the disclosure.

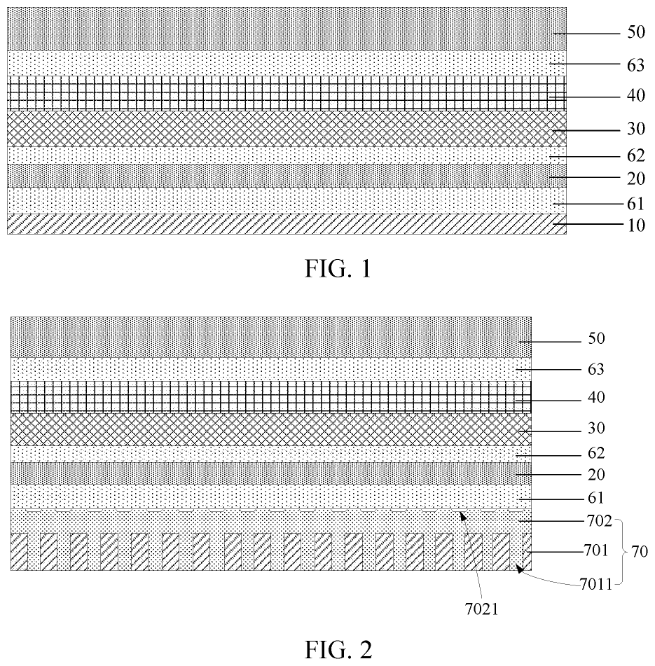

As shown in FIG. 1, FIG. 1 is a schematic diagram of a structure of some flexible display modules. The flexible display modules include a supporting member 10 of a metal material, and a support film 20, a display structure layer 30, a module function layer 40 and a cover plate 50 which are stacked sequentially on the supporting member 10. The module functional layer 40 may include a touch structure layer and a polarizer. The display structure layer 30 may be an OLED display structure layer and may include a flexible base substrate, a driving structure layer, a light-emitting structure layer and an encapsulation structure layer. The supporting member 10 and the support film 20, the support film 20 and the display structure layer 30, and the module function layer 40 and the cover plate 50 are bonded to each other by a first adhesive layer 61, a second adhesive layer 62, and a third adhesive layer 63, respectively. The supporting member 10 of the metal material in FIG. 1 may be designed as an entire solid. In order to meet requirements of bending or rolling of the flexible display module, a thickness of the supporting member 10 should not be too high. If the thickness is increased, the metal supporting member 10 is prone to breakage. The thickness of the supporting member 10 may be controlled to be from 15 μm (micrometer) to 50 μm, and an actual thickness may be selected depending on different bending radii. In the flexible display module of FIG. 1, the supporting member 10 of the metal material mainly serves to flatten the flexible display module deformed by bending or rolling, improve creases, and meet demands of fixing when assembling the flexible display module with other modules of the display device. Due to decrease of the bending radius of the flexible display module or the requirement of rolling, higher requirements are put forward for enhancement of the bending resistance or fatigue resistance (or deformation ability) of the supporting member 10.

In order to improve the bending resistance or fatigue resistance of the supporting member of the metal material, in some schemes, the supporting member is patterned, such as by providing multiple through holes at local positions on the supporting member or the whole supporting member to meet requirement of smaller bending radius or requirement of rolling of the flexible display module, and stress exerted by the support provided with the multiple through holes to the display structure layer can be reduced. As shown in FIG. 2, FIG. 2 is a schematic diagram of a structure of some other flexible display modules. Compared with the flexible display module of FIG. 1, the flexible display module of FIG. 2 employs a patterned supporting member. The flexible display module includes a supporting member 70, and a support film 20, a display structure layer 30, a module function layer 40, and a cover plate 50 that are sequentially stacked on the supporting member 70. The module functional layer 40 may include a touch structure layer and a polarizer. The display structure layer 30 may be an OLED display structure layer and may include a flexible base substrate, a driving structure layer, a light-emitting structure layer and an encapsulation structure layer. The supporting member 70 and the support film 20, the support film 20 and the display structure layer 30, and the module function layer 40 and the cover plate 50 are bonded to each other by a first adhesive layer 61, a second adhesive layer 62, and a third adhesive layer 63, respectively. The first adhesive layer 61, the second adhesive layer 62, and the third adhesive layer 63 may all be made of optically transparent adhesive materials, and the materials of the three adhesive layers may all include acrylic (i.e. polymethyl methacrylate).

The supporting member 70 may include a substrate 701 of a metal material and a planarization layer 702, wherein the substrate 701 is provided with multiple through holes 7011 and the planarization layer 702 is provided on a surface of the substrate 701 facing the display structure layer 30 and filled in the multiple through holes 7011. In a process of preparing the planarization layer 702, a liquid material that can be used for forming the planarization layer 702 by a coating process (for example, a curable viscous organic polymer material such as silica gel or acrylic) is filled in the multiple through holes 7011 of the substrate 701, the planarization layer 702 is formed after flattened and cured on the surface of the substrate 701, such that the supporting member 70 has a relatively flat surface and surface flatness of the supporting member 70 is ensured. The planarization layer 702 and the substrate 701 form an integral structure, and the planarization layer 702 can enhance connection strength and breaking strength of the substrate 701 provided with the multiple through holes 7011, and can also function in buffering stress.

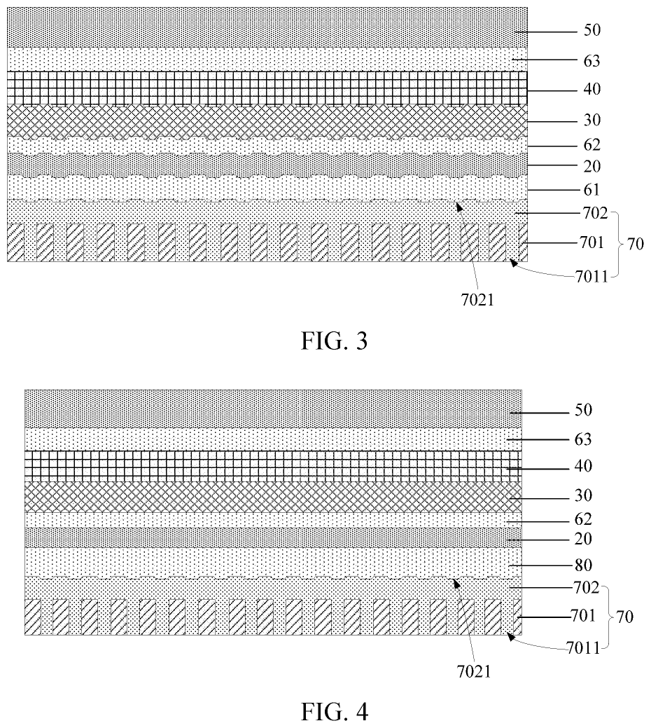

After making some samples, the inventor of the present application discovered that, the supporting member 70 in this example, due to a capillary function of portions of the planarization layer 702 filled in the multiple through holes 7011, pits 7021 are formed on the surface of the planarization layer 702 corresponding to the positions of the multiple through holes 7011, after the supporting member 70 is attached to other structure layers of the flexible display module, these pits 7021 are transferred by impression between layers, which will further form stamps which are transferred to the display structure layer (such as the flexible OLED display structure layer) 30, and finally will be displayed on the screen, resulting in defected appearance and affecting the displaying, as shown in FIG. 3. Although the thickness of the flexible display module can eliminate the pits that are eventually transferred to the display structure layer 30 to some extent, there is no method for completely solving the stamping problem of the pits.

As shown in FIG. 4, FIG. 4 is a schematic diagram of structure of a flexible display module for eliminating the stamps in the pits. In FIG. 4, a first buffer layer 80 is provided between a planarization layer 702 of a supporting member 70 and a support film 20 adjacent to the planarization layer 702. A material of the first buffer layer 80 may be foam or the like, for example, the first buffer layer 80 is foam glue, which can attach the supporting member 70 to the support film 20. In the flexible display module of FIG. 4, the support film 20 and the second adhesive layer 62 may not be provided and the first buffer layer 80 is provided between the planarization layer 702 of the supporting member 70 and the display structure layer 30. The first buffer layer 80 can eliminate the stamps of the pits 7021 of the planarization layer 702 of the supporting member 70 and improve the appearance of the flexible display module.

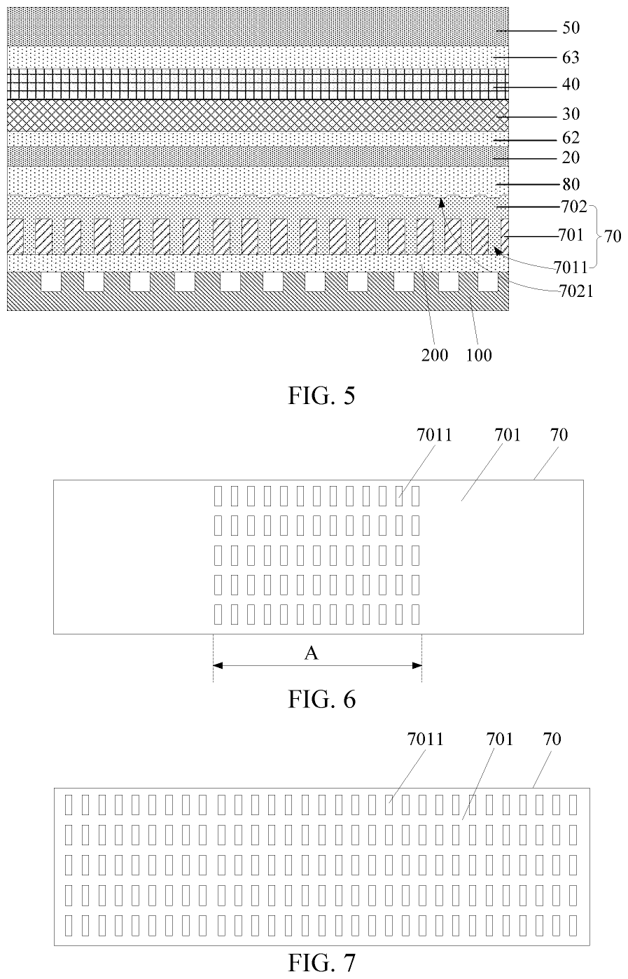

In some examples, the schematic diagram of the structure of the flexible display module in FIG. 4 when finally combined on an overall unit of a display device may be shown in FIG. 5. In FIG. 5, a side of the supporting member 70 facing away from the display structure layer 30 is fixed to an overall unit frame 100. A second buffer layer 200 is provided between the surface of the supporting member 70 facing away from the display structure layer 30 and the overall unit frame 100. The second buffer layer 200 may be made of a material such as foam, for example, the second buffer layer 200 may be made of foam glue, which may function as a connection between the supporting member 70 and the overall unit frame 100, and can also buffer bumping impact of the overall unit frame 100 on the flexible display module or the like. By way of example, the display device may be a foldable display device, and correspondingly the overall unit frame 100 may be provided with a hinge portion corresponding to a position of a bending region of the flexible display module.

In some examples, in the flexible display module of FIG. 4, the multiple through holes 7011 on the substrate 701 of the supporting member 70 may be provided in a partial region of the substrate 701 or the multiple through-holes 7011 may be distributed over the entire surface of the substrate 701.

The flexible display module may be used for a foldable display device or a rollable display device. In a case that the flexible display module is used in a foldable display device, the flexible display module may have a bending region, which is in a bent form when the flexible display module is in a folded state and flattened when the flexible display module is in a unfold state. As shown in FIG. 6, FIG. 6 shows a schematic diagram of a top view structure of a supporting member, the multiple through holes 7011 may be provided at a position A of the substrate 701 of the supporting member 70 corresponding to a bending region of the flexible display module, and the rest of regions of the substrate 701 may not be provided with through holes. In a case that the flexible display module is used for a rollable display device, the flexible display module can be rolled and unfold, and accordingly, as shown in FIG. 7, the multiple through holes 7011 may be provided on the entire surface of the substrate 701 of the supporting member 70, that is, the multiple through holes 7011 are distributed over the entire surface of the substrate 701.

In the flexible display module of FIG. 4 described above, the stamping problem of the pits is improved by providing the first buffer layer 80, however, elastic modulus of the first buffer layer 80 is generally in a kPa (kilo Pascal) level, and a low elastic modulus will greatly weakens rebound effects of the supporting member 70, thereby affecting an improvement effect of the supporting member 70 on a crease after the bending or rolling of the flexible display module. In addition, when the display structure layer 30 needs compressive stress of the supporting member 70 to conduct protection, existence of the first buffer layer 80 will affect forces exerted on the display structure layer 30, and the supporting member 70 cannot function as a protection for the display structure layer 30. In addition, deformation of the first buffer layer 80 is relatively large, and irreversible deformation is more likely to be generated.

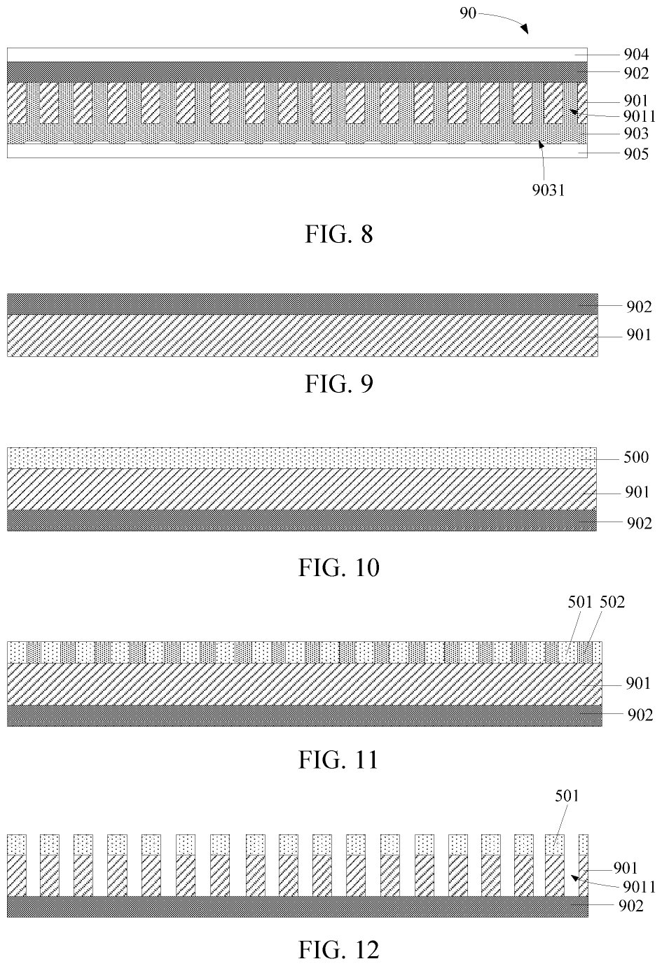

In this regard, the embodiment of the present disclosure provides a structure of a supporting member. As shown in FIG. 8, the supporting member 90 of this embodiment includes a substrate 901 of a metal material, a first planarization layer 902 and a second planarization layer 903. The substrate 901 is provided with multiple through holes 9011, wherein the multiple through holes 9011 run through a first surface and a second surface of the substrate 901 which are opposite to each other. The first planarization layer 902 is provided on the first surface, and the second planarization layer 903 is provided on the second surface and filled in the multiple through holes 9011.

In a case that the supporting member 90 of this embodiment is attached to other structure layers of the flexible display module, the first planarization layer 902 of the supporting member 90 is provided towards a display side of the flexible display module. Since the first planarization layer 902 of the supporting member 90 of this embodiment is not filled in the through holes 9011 of the substrate 901, such that pits will not not formed on the surface of the first planarization layer 902, thus avoiding the problem of pits stamping and greatly optimizing the appearance of the flexible display module. Moreover, the supporting member 90 of this embodiment maintains resilience of the substrate 901 to a large extent, and the supporting member 90 has good resilience, which can ensure the capability of improving the crease of the flexible display module.

In some exemplary embodiments, the material of the substrate 901 may include any one or more of a nickel-iron alloy (Ni—Fe), a copper-zinc alloy (Cu—Zn). Elastic modulus of the substrate 901 may be 50 GPa (giga Pascal) to 300 GPa.

In some exemplary embodiments, a thickness of the substrate 901 may be 50 μm to 300 μm. For example, in a case that the thickness of the base plate 901 is 150 μm, the R4, 200K dynamic bending test is satisfied, that is, the supporting member of this example does not break after repeated bending for 200K (200,000) times in a case that a bending radius R=4 mm.

In some exemplary embodiments, a material of the first planarization layer may include polyimide. Elastic modulus of the first planarization layer 902 may be 1 GPa to 10 GPa. The first planarization layer 902 may have a thickness of 10 μm to 30 μm, for example 15 μm.

In some exemplary embodiments, a material of the second planarization layer 903 may include any one or more of silica gel, acrylic. Elastic modulus of the second planarization layer 903 may be 0.5 MPa (mega pascal) to 50 MPa.

In some exemplary embodiments, portions of the second planarization layer 903 filled in the through holes 9011 of the substrate 901 completely fill the through holes 9011, and portions of the second planarization layer 903 on the second surface of the substrate 901 may have a thickness of 20 μm to 100 μm. Pits 9031 are formed on a surface of the second planarization layer 903 at positions corresponding to the through holes 9011. However, the second planarization layer 903 is provided away from the display side of the flexible display module when the supporting member 90 is attached to other structure layers of the flexible display module, so that there will not be the pit stamping problem as described above.

In some exemplary embodiments, the multiple through holes 9011 are provided in a partial region of the substrate 901, or distributed over the entire surface of the substrate 901. The multiple through holes 9011 may be provided on the substrate 901 in a same manner as the through holes provided on the substrate of the supporting member in FIG. 6 and FIG. 7 in the previous embodiments.

In some exemplary embodiments, the supporting member 90 may further include a first protection film 904 provided on a side of the first planarization layer 902 away from the substrate 901, and a second protection film 905 provided on a side of the second planarization layer 903 away from the substrate 901. Both of the first protection film 904 and the second protection film 905 function as a protection, and the first protection film 904 and the second protection film 905 may be removed when the supporting member 90 is attached to other structure layers of the flexible display module as well as when the flexible display module is assembled with an overall unit of a display device.

Based on the structure of the supporting member of the flexible display module in FIG. 8, an embodiment of the present disclosure further provides a method for preparing the supporting member of the flexible display module, including:

forming a first planarization layer on a first surface of a substrate of a metal material;

forming multiple through holes on the substrate, wherein the multiple through holes run through the first surface and a second surface of the substrate which are opposite to each other; and

forming a second planarization layer on the second surface of the substrate, wherein the second planarization layer is provided on the second surface of the substrate and filled in the multiple through holes.

A method for preparing a supporting member of a flexible display module according to an embodiment of the present disclosure will be described below with reference to FIG. 9 to FIG. 14, and the preparation method includes the following steps:

1) Forming a first planarization layer on a first surface of a substrate 901 of a metal material, as shown in FIG. 9; A method for forming the first planarization layer 902 is to press the first planarization film onto the first surface of the substrate 901 of the metal material by a hot pressing process, thereby forming the first planarization layer 902 on the first surface of the substrate 901. A material of the first planarization film may include thermoplastic polyimide, and a temperature of the hot pressing process is required to be higher than a thermal softening temperature of the first planarization film, and the temperature of the hot pressing process may be above 250° C., such as 300° C., a pressure may be 0.8 N to 1.0 N, and time may be 10 s to 30 s. In the hot pressing process, rollers or pressing plates may be employed for pressing.

Another method for forming the first planarization layer 902 may be that a liquid material (e.g. including polyimide) used for forming the first planarization layer 902 is coated on the first surface of the substrate 901 by a coating process, and the first planarization layer 902 is formed after curing.

The material of the first planarization layer 902 may be polyimide and elastic modulus of the first planarization layer 902 may be 1 GPa to 10 GPa. The elastic modulus of the first planarization layer 902 made of polyimide is much higher than that of a material such as foam or silica gel (the elastic modulus is in a level of kPa to MPa), so that the resilience of the first planarization layer 902 made of polyimide is better, and the elastic modulus of the whole supporting member finally prepared is not lost too much, thus ensuring the demand for resilience.

The first planarization layer 902 may have a thickness of 10 μm to 30 μm for example 15 μm.

The material of the substrate 901 may include any one or more of a nickel-iron alloy (Ni—Fe), a copper-zinc alloy (Cu—Zn). Elastic modulus of the substrate 901 may be 50 GPa to 300 GPa. A thickness of the substrate 901 may be 50 μm to 300 μm, for example 150 μm.

In this step, after the first planarization layer 902 is formed on the first surface of the metal substrate 901, the substrate 901 and the first planarization layer 902 form an integral coil.

2) Forming multiple through holes 9011 on the substrate 901, wherein the multiple through holes 9011 run through the first surface and the second surface of the substrate 901 which are opposite to each other. By way of example, the multiple through holes 9011 may be formed on the substrate 901 using a photolithography process, including steps of: coating photoresist, exposing, developing, etching and removing photoresist and the like.

a. Coating photoresist: as shown in FIG. 10, a photoresist (PR) is coated on the second surface of the substrate 901, and a photoresist layer 500 is formed after curing.

b. Exposing: as shown in FIG. 11, the photoresist layer 500 may be exposed using a mask so that the exposed photoresist layer 500 includes an exposed region 502 and an unexposed region 501.

c. Developing and etching: as shown in FIG. 12, the exposed region 502 or the unexposed region 501 of the photoresist layer 500 is dissolved with a developing liquid. Herein, the photoresist forming the photoresist layer 500 may be a positive photoresist or a negative photoresist. If the photoresist is positive, the developing liquid will dissolve the exposed region 502 of the photoresist layer 500, while the unexposed region 501 will not be dissolved. If the photoresist is negative, the developing liquid will dissolve the unexposed region 501 of the photoresist layer 500, while the exposed region 502 will be not be dissolved. In this example, the photoresist is a positive photoresist, and after development, the exposed region 502 of the photoresist layer 500 is dissolved and the substrate 901 below the exposed region 502 is exposed, while the unexposed region 501 is retained to protect the substrate 901 below the unexposed region 501.

Subsequently, under the protection of the unexposed region 501 of the photoresist layer 500, the exposed region of the substrate 901 is etched with an etchant (strong acid or strong base) and multiple through holes 9011 are formed. During developing and etching, the first planarization layer 902 on the first surface of the substrate 901 does not react and a flat appearance may be retained. The material of the first planarization layer 902 needs to be non-reactive with the etchant, and the material of the first planarization layer 902 may be an organic polymer material such as polyimide.

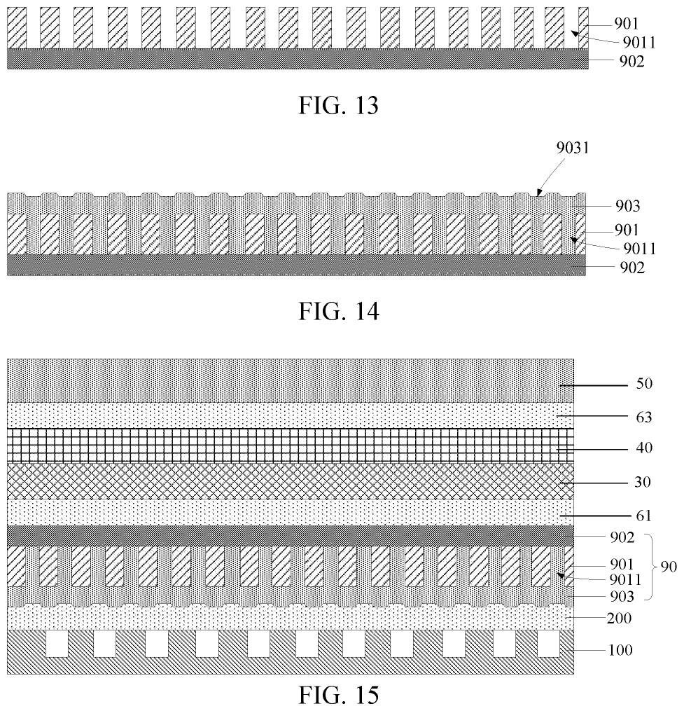

d. Removing photoresist: as shown in FIG. 13, the unexposed region 501 of the photoresist layer 500 is peeled off from the substrate 901.

3) Forming a second planarization layer 903 on the second surface of the substrate 901 on which the multiple through holes 9011 are formed, and the second planarization layer 903 is provided on the second surface of the substrate 901 and filled in the multiple through holes 9011, as shown in FIG. 14. A liquid material for forming the second planarization layer 903 may be coated on the second surface of the substrate 901 by a coating process, wherein the liquid material for forming the second planarization layer 903 is filled in the multiple through holes 9011, flattened on the second surface of the substrate 901, and the second planarization layer 903 is formed after curing. The second planarization layer 903 formed by coating forms pits 9031 at surface positions corresponding to the multiple through holes 9011 due to a capillary function.

4) Covering the first planarization layer 902 and the second planarization layer 903 with a first protection film 904 and a second protection film 905, respectively, as shown in FIG. 8. Both the first protection film 904 and the second protection film 905 may function as a protection. The first protection film 904 and the second protection film 905 are removed when the supporting member is attached to other structure layers of the flexible display module as well as when the flexible display module is assembled with an overall unit of a display device.

A method for preparing a supporting member according to the embodiment of the present disclosure includes: first, forming a first planarization layer 902 on a first surface of a substrate 901 of a metal material; then, forming through holes 9011 on the substrate 901; then, forming a second planarization layer 903 on a second surface of the substrate 901. Therefore, since the first planarization layer 902 is formed in advance before the through holes 9011 are formed, and the first planarization layer 902 is not filled in the through holes 9011, thus no physical pits will be formed on the surface of the first planarization layer 902. Furthermore, after the supporting member prepared according to the embodiment of the present disclosure is attached to other structure layers of the flexible display module, the first planarization layer 902 of the support is provided towards the display side of the flexible display module. Since there are no pits formed on the first planarization layer 902, the problem of pits stamping is greatly reduced or avoided, and the appearance of the flexible display module is greatly optimized. Furthermore, the supporting member of the embodiment of the present disclosure can greatly maintain the resilience of the substrate 901 and the supporting member has good resilience to ensure the capability of improving creases of the flexible display module.

The embodiment of the present disclosure further provides a flexible display module, as shown in FIG. 15, FIG. 15 shows a schematic diagram of a structure of the flexible display module of the embodiment of the present disclosure fixed to an overall unit frame 100. The flexible display module includes a supporting structure layer and a display structure layer 30 provided on the supporting structure layer, wherein the supporting structure layer includes the supporting member 90 described in the previous embodiment, and the first planarization layer 902 is provided towards the display structure layer 30.

In some exemplary embodiments, as shown in FIG. 15, the display structure layer 30 may be provided on the first planarization layer 902, and the display structure layer 30 may be attached to the supporting member 90 by a first adhesive layer 61. In an example of this embodiment, the display structure layer 30 may include a flexible base substrate, and a driving structure layer, a light-emitting structure layer, and an encapsulation structure layer sequentially provided on the flexible base substrate, wherein the flexible base substrate is attached to the first planarization layer 902 by the first adhesive layer 61.

In some exemplary embodiments, as shown in FIG. 15, the flexible display module may further include a module function layer 40 and a cover plate 50 sequentially provided on the display structure layer 30, wherein the module function layer 40 may include a touch structure layer and a polarizer. In an example of this embodiment, the touch structure layer may be provided on the display structure layer 30, and the module function layer 40 may be attached to the cover plate 50 by a third adhesive layer 63. The cover plate 50 may be made of a flexible material such as transparent polyimide.

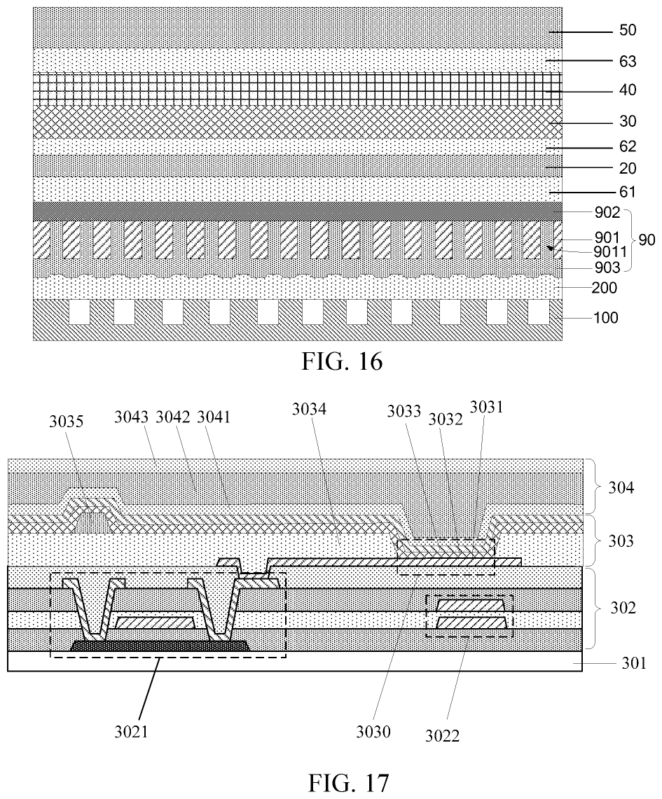

In some exemplary embodiments, as shown in FIG. 16, the supporting structure layer may further include a support film 20 provided on a side of the supporting member 90 facing the display structure layer 30, wherein the support film 20 is provided on the planarization layer 902 and the display structure layer 30 is provided on the support film 20. In one example of this embodiment, the support film 20 and the supporting member 90 may be attached to each other by the first adhesive layer 61. The display structure layer 30 and the support film 20 may be attached to each other by a second adhesive layer 62. As an example, the support film 20 may be any one or more of polyethylene terephthalate (PET) or polyimide (PI), and the support film 20 may function in supporting and protecting the display structure layer 30.

In some exemplary embodiments, the first adhesive layer 61, the second adhesive layer 62, and the third adhesive layer 63 may all be made of optically transparent adhesive materials, and the materials of the three adhesive layers may all include acrylic (i.e. polymethyl methacrylate).

In some exemplary embodiments, as shown in FIG. 17, the display structure layer 30 may be an OLED display structure layer including a flexible base substrate 301, along with a driving structure layer 302, a light-emitting structure layer 303, and an encapsulation structure layer 304 sequentially provided on the flexible base substrate 301. By way of example, the light-emitting structure layer 303 includes multiple OLED devices 3030 defined by a pixel define layer 3034, wherein each OLED device 3030 includes a first electrode 3031, an organic functional layer 3032, and a second electrode 3033 which are stacked. The light-emitting structure layer 303 may further include a support pad 3035 provided on the pixel define layer 3034. The driving structure layer 302 includes pixel driving circuits, wherein each of the pixel driving circuits is configured to drive a corresponding one of the OLED devices 3030 to emit light, and each of the pixel driving circuits includes multiple thin film transistors 3021 and a storage capacitor 3022. A drain electrode of a driving transistor in the multiple thin film transistors 3021 is connected to a first electrode 3031 of an OLED device 3030. The encapsulation structure layer may include a first inorganic layer 3041, an organic encapsulation layer 3042, and a second inorganic layer 3043 which are stacked.

By way of example, as shown in FIG. 17, the flexible base substrate 301 may include a substrate and a buffer layer provided on the substrate for improving water oxygen resistance of the substrate. The drive structure layer 302 includes an active layer provided on the flexible base substrate 301, a first insulating layer covering the active layer, a first gate metal layer provided on the first insulating layer, a second insulating layer covering the first gate metal layer, a second gate metal layer provided on the second insulating layer, a third insulating layer covering the second gate metal layer, a source and drain metal layer provided on the third insulating layer, a fourth insulating layer covering the source and drain metal layer. The first gate metal layer at least includes a gate electrode and a first capacitor electrode. The second gate metal layer at least includes a second capacitor electrode. The source-drain metal layer at least includes a source electrode and a drain electrode. The active layer, the gate electrode, the source electrode and the drain electrode form a drive transistor 3021. The first capacitor electrode and the second capacitor electrode form a storage capacitor 3022. The light-emitting structure layer 303 is provided on the driving structure layer 302 and the first electrode 3031 is connected to the drain electrode of the driving transistor 3021 by a via provided on the fourth insulating layer. The first insulating layer and the second insulating layer are called Gate Insulating (GI) layers. The third insulating layer is called an Interlayer Insulating (ILD) layer. The fourth insulation layer is called a Planarization (PLN) layer. The buffer layer, the first insulating layer, the second insulating layer, and the third insulating layer may be made of any one or more of silicon oxide (SiOx), silicon nitride (SiNx), and silicon oxynitride (SiON). The fourth insulating layer may be made of an organic insulating material, such as polyimide. The first gate metal layer and the second gate metal layer may be made of a metal material, such as any one or more of silver (Ag), copper (Cu), aluminum (Al), titanium (Ti), and molybdenum (Mo), or an alloy material of the aforementioned metals. The active layer may be made of a material such as amorphous indium gallium zinc oxide (a-IGZO), zinc oxynitride (ZnON), indium zinc tin oxide (IZTO), amorphous silicon (a-Si), polysilicon (p-Si), hexathiophene, or polythiophene, etc. That is, the present disclosure is applicable to transistors that are manufactured based on oxide technology, silicon technology and organic technology.

An embodiment of the present disclosure further provides a display device, as shown in FIG. 15 and FIG. 16. The display device includes an overall unit frame 100, a flexible display module described in the previous embodiment and provided on the overall unit frame 100, and a second buffer layer 200, wherein the second buffer layer 200 is provided between a supporting member 90 of the flexible display module and the overall unit frame 100.

In some exemplary embodiments, a material of the second buffer layer 200 may include foam, such as foam glue, which may function as a connection between the supporting member 90 and the overall unit frame 100, and may buffer, such as bumping impacts that the overall unit frame 100 may bring to the flexible display module.

The display device of the embodiment of the present disclosure may be a foldable display device or a rollable display device. The display device of the embodiment of the present disclosure may be any product or component with a display function, such as a mobile phone, a tablet computer, a television, a display, a laptop computer, a digital photo frame, or a navigator.

In the description herein, orientation or positional relations indicated by terms “up”, “down”, “left”, “right”, “top”, “inside”, “outside”, “axial direction”, “four corners” and the like are based on the orientation or positional relations shown in the drawings, and are for ease and brief description of the present disclosure and are not intended to indicate or imply that the structures referred to must have a specific orientation, or be constructed and operated in a particular orientation, and therefore these terms should not be construed as limitations on the present disclosure.

In the description herein, the terms “connection”, “fixed connection”, “installation” and “assembly” are to be understood in a broad sense, for example, a connection may be a fixed connection, or a detachable connection, or may be an integral connection, unless explicitly specified and defined otherwise. The terms “installation”, “connection” and “fixed connection” may refer to a direct connection, or may an indirect connection through an intermediate medium, or may be an internal connection between two elements. Those of ordinary skills in the art may understand the meanings of the terms in the present disclosure.

1. A supporting member for a flexible display module, comprising a substrate of a metal material, a first planarization layer and a second planarization layer, wherein the substrate is provided with a plurality of through holes running through a first surface and a second surface of the substrate which are opposite to each other, the first planarization layer is provided on the first surface, and the second planarization layer is provided on the second surface and filled in the plurality of through holes.

2. The supporting member of the flexible display module according to claim 1, wherein a material of the first planarization layer comprises polyimide.

3. The supporting member of the flexible display module according to claim 1, wherein an elastic modulus of the first planarization layer is 1 GPa to 10 GPa.

4. The supporting member of the flexible display module according to claim 1, wherein the first planarization layer has a thickness of 10 μm to 30 μm.

5. The supporting member of the flexible display module according to claim 1, wherein a material of the substrate comprises any one or more of a nickel-iron alloy, a copper-zinc alloy.

6. The supporting member of the flexible display module according to claim 1, wherein the substrate has a thickness of 50 μm to 300 μm.

7. The supporting member of the flexible display module of claim 1, wherein a material of the second planarization layer comprises any one or more of silica gel, acrylic.

8. A flexible display module, comprising a supporting structure layer and a display structure layer provided on the supporting structure layer, wherein the supporting structure layer comprises the supporting member of the flexible display module according to claim 1, the first planarization layer is provided towards the display structure layer.

9. The flexible display module according to claim 8, wherein the display structure layer is provided on the first planarization layer, and the display structure layer and the supporting member are attached to each other by an adhesive layer.

10. The flexible display module according to claim 8, wherein the supporting structure layer further comprises a support film provided on a side of the supporting member facing the display structure layer, the support film is provided on the first planarization layer, and the display structure layer is provided on the support film.

11. The flexible display module according to claim 8, wherein the display structure layer comprises a flexible base substrate, and a driving structure layer, a light-emitting structure layer and an encapsulation structure layer sequentially provided on the flexible base substrate, the light-emitting structure layer comprises a plurality of OLED devices, and the driving structure layer comprises pixel driving circuits configured to drive the OLED devices to emit light.

12. A display device, comprising the flexible display module according to claim 8.

13. A method for preparing a supporting member of a flexible display module, comprising:
forming a first planarization layer on a first surface of a substrate of a metal material;
forming a plurality of through holes on the substrate, wherein the plurality of through holes run through the first surface and a second surface of the substrate which are opposite to each other; and
forming a second planarization layer on the second surface of the substrate, and the second planarization layer is provided on the second surface of the substrate and filled in the plurality of through holes.

14. The method for preparing the supporting member of the flexible display module according to claim 13, wherein forming the first planarization layer on the first surface of the substrate of the metal material comprises pressing a first planarization film on the first surface of the substrate of metal material by a hot pressing process, so that the first planarization layer is formed on the first surface of the substrate.

15. The method for preparing the supporting member of the flexible display module according to claim 14, wherein a material of the first planarization film comprises a thermoplastic polyimide, and the hot pressing process has a temperature of 250° C. or higher, a pressure of 0.8 N to 1.0 N, and time of 10 s to 30 s.

16. The method for preparing the supporting member of the flexible display module according to claim 13, wherein forming the first planarization layer on the first surface of the substrate of the metal material comprises coating a liquid material for forming the first planarization layer on the first surface of the substrate by a coating process, and forming the first planarization layer after curing.

17. The method for preparing the supporting member of the flexible display module according to claim 13, wherein a material of the first planarization layer comprises polyimide.

18. The method for preparing the supporting member of the flexible display module according to claim 13, wherein forming the plurality of through holes on the substrate comprises forming the plurality of through holes on the substrate by a photolithography process.

19. The method for preparing the supporting member of the flexible display module according to claim 13, wherein forming the second planarization layer on the second surface of the substrate, and the second planarization layer being provided on the second surface of the substrate and filled in the plurality of through holes comprises:
coating a liquid material for forming a second planarization layer on the second surface of the substrate by a coating process, filling the liquid material for forming the second planarization layer in the plurality of through holes, flattening on the second surface of the substrate, and forming the second planarization layer after curing.

20. The method for preparing the supporting member of the flexible display module according to claim 13, wherein a material of the substrate comprises any one or more of nickel-iron alloy, copper-zinc alloy, and a material of the second planarization layer comprises any one or more of silica gel, acrylic.
